(19) United States
(12) Patent Application Publication
(10) Pub. No.: US 2021/0150106 A1
(43) Pub. Date: May 20, 2021

(54) MACHINE LEARNING SYSTEM AND METHOD FOR PROPULSION SIMULATION

(71) Applicant: Michael R. Limotta, III, Buellton, CA (US)

(72) Inventor: Michael R. Limotta, III, Buellton, CA (US)

(21) Appl. No.: 16/674,556

(22) Filed: Nov. 5, 2019

(51) Int. Cl. G06F 30/27; G06N 3/10; G06N 3/08; G06F 30/28

(52) U.S. Cl. CPC G06F 30/27; G06F 30/28; G06N 3/08; G06N 3/10

(57) ABSTRACT

A combustion propulsion engine simulation system is described. The system includes a first computer processor environment configured to preprocess data for providing to a simulation environment, the computer processor environment including a graphical user interface (GUI) for receiving input from a user. The system also includes a second computer processor environment running at least partially trained neural network software that has been trained to model the dynamics of at least a portion of a combustion propulsion engine when in use, the second computer processor environment receiving input information from the first computer processor environment. Further, the system includes a third computer processor environment configured to receive data related to the output from the neural network of the second computer processor environment, the third computer processor environment providing post processing based on inputs received from a user through a GUI running on the third computer processor environment.

### BACKGROUND

Powerful combustion propulsion engines such as jet and rocket engines remain an area of industrial, commercial and academic interest. Their value lies in propelling expensive and massive vehicles such as aircraft and spacecraft. Development of these types of powerful propulsion systems require an enormous amount of engineering development, research, and optimization. Today, much of the development is done even before an engine is created through many, many hours of numerical simulation and numerical design. Because the basis of these propulsion systems is combustion and fluid flowing out of an orifice, the mathematics in modeling this is extremely complex and impossible to solve explicitly. Therefore, engineers rely on simulation through numerical methods known as computational fluid dynamics (CFD). CFD is typically a means to solving numerically the Navier-Stokes differential equations in order to model the fluid dynamic flow through the propulsion system or alternatively in flow through parts of the system. Also, Finite Element modelling is a numerical method that may be used to determine the reaction of the structure to the combustion and fluid flow through the system. The disadvantage to all of this numerical modelling is that it can be very time consuming, both setting up the model for a given system as well as carrying out the innumerable calculations required to solve the problems. Further, as these systems are highly turbulent in nature a turbulence model must also be applied. These turbulence models, mostly based off of the Navier-Stokes equations, require so much computational overhead and expense that it may be necessary to utilize less accurate assumptions.

Accordingly, there is a need for ways to simulate the dynamics of a propulsion system, such as, but not limited to a rocket engine or a jet engine or the like. There is also a need for reducing the computational time as well as the time for setting up a simulation that does not require enormous computational overhead in providing a reasonable simulation result.

### SUMMARY

An exemplary embodiment relates to a combustion propulsion engine simulation system. The system includes a first computer processor environment configured to preprocess data for providing to a simulation environment, the computer processor environment including a graphical user interface (GUI) for receiving input from a user. The system also includes a second computer processor environment running at least partially trained neural network software that has been trained to model the dynamics of at least a portion of a combustion propulsion engine when in use, the second computer processor environment receiving input information from the first computer processor environment. Further, the system includes a third computer processor environment configured to receive data related to the output from the neural network of the second computer processor environment, the third computer processor environment providing post processing based on inputs received from a user through a GUI running on the third computer processor environment.

Another exemplary embodiment relates to a method of simulating dynamics of a combustion propulsion engine. The method includes receiving input from a user through a graphical user interface (GUI) running on a first computer environment. The method also includes preprocessing data, by the first computer processor environment and receiving input information, by a second computer processor environment, from the first computer processor environment. Further, the method includes running at least partially trained neural network software, by a second computer processor environment, that has been trained to model the dynamics of at least a portion of a combustion propulsion engine when in use. Further still, the method includes receiving data, by a third computer processor environment, the data being related to the output from the neural network of the second computer processor environment and providing post processing, by a third computer processor environment, the post processing based on inputs received from a user through a GUI running on the third computer processor environment.

Yet another exemplary embodiment relates to a system for simulating dynamics of a combustion propulsion engine. The system includes a means for receiving input from a user through a graphical user interface (GUI) running on a first computer environment and a means for preprocessing data, by the first computer processor environment. The method also includes a means for receiving input information, by a second computer processor environment, from the first computer processor environment and a means for running at least partially trained neural network software, by a second computer processor environment, that has been trained to model the dynamics of at least a portion of a combustion propulsion engine when in use. Further, the method includes a means for receiving data, by a third computer processor environment, the data being related to the output from the neural network of the second computer processor environment, and a means for providing post processing, by a third computer processor environment, the post processing based on inputs received from a user through a GUI running on the third computer processor environment.

In addition to the foregoing, other system aspects are described in the claims, drawings, and text forming a part of the disclosure set forth herein. The foregoing is a summary and thus may contain simplifications, generalizations, inclusions, and/or omissions of detail; consequently, those skilled in the art will appreciate that the summary is illustrative only and is NOT intended to be in any way limiting. Other aspects, features, and advantages of the devices and/or processes and/or other subject matter described herein will become apparent in the disclosures set forth herein.

### BRIEF DESCRIPTION OF THE DRAWINGS

FIG. 1 is an exemplary embodiment of a stack of a software system for an artificial neural network combustion propulsion engine simulation system.

FIG. 2 is an exemplary embodiment of a flow diagram for an artificial neural network combustion propulsion engine simulation system.

FIG. 3 is an exemplary embodiment of a flow diagram for an artificial neural network combustion propulsion engine simulation system.

The use of the same symbols in different drawings typically indicates similar or identical items unless context dictates otherwise.

### DETAILED DESCRIPTION

Generally, the purpose of modelling and simulation of a combustion propulsion engine, are understanding the steady state operation and transient operation of the engine. For example, it may be desirable to model fluid, chemical, and structural aspects of the engine. The steady state operation may consist of investigation of the operating equilibrium regimes. An appropriate model for the engine fluid dynamics may be based on describing the operation of a combustion propulsion engine at design and off-design regimes. Conventionally the dynamic modeling of the turbojet engine is obtained from the energy balance equation for compressor, combustor and turbine, as the engine's main parts. The transient analysis, which is based on appropriate modeling of engine and its main parts, expresses the dynamic behavior of the turbojet engine, and further, provides details regarding the engine's control. The aim of the dynamic analysis is to determine a control program for the turbojet, based on the results provided by performance analysis. For example, in the case of a single-spool turbojet engine, with fixed nozzle geometry, the thrust is controlled by one parameter, which is the fuel flow rate. The design and management of the aircraft engine controls are based on the results of the transient analysis. Other aspects may also be modeled such as, but not limited to predictions of fluid dynamics, combustion products, and mixture ratios for finite volumes within the engine. Conventionally, the construction of the design model is complex, since it is based on both steady-state and transient analysis through numerical processes like CFD. Thus, it would be advantageous to provide modelling both steady state and transient through other means which may not require the computational overhead that a CFD model demands.

An artificial neural network (ANN) is a system that, due to its topological structure, can adaptively learn nonlinear mappings from input to output space when the network has a large database of prior examples from which to draw. In some sense, an ANN simulates human functions such as learning from experience, generalizing from previous to new data, and abstracting essential characteristics from inputs containing irrelevant data. Using an ANN for propulsion system modelling, without the need for significant physical modeling or insight, may be highly advantageous because in an ANN, the source terms are highly nonlinear functions of the input parameters. Hence, linear interpolation is not an appropriate approach to their modeling, unless each parameter of the data set is divided into an enormous number of small increments.

The basic architecture of a neural network includes layers of interconnected processing units called neurons (comparable to the dendrites in the biological neuron) that transform an input vector [c1, c2, . . . , cM]T into an output vector[a1n, a2n, . . . , aSn]T. Neurons without predecessors are called input neurons and constitute the input layer. All other neurons are called computational units because they are developed from the input layer. A nonempty subset of the computational units is specified as the output units. All computational units that are not output neurons are called hidden neurons.

The universal approximation theorem states that a neural network with one hidden layer, utilizing a sigmoid transfer function, is able to approximate any continuous function f: R M→R S2 (where M and S2 are dimensions of the function domain and range, respectively) in any domain, with a given accuracy based, in part, on the amount of training data. Features of the input data are extracted in the hidden layer with a hyperbolic tangent transfer function and in the output layer with a purely linear transfer function. Based on the theorem and thanks to the topological structure of the neural network, one can generate complex data dependencies without performing time-consuming computations. However, any neural network application depends on the training or learning algorithm. The learning algorithm is the repeated process of adjusting weights to minimize the network errors. These errors are defined by e=t−a, where t is the desired network output vector and a=a(c, [W]) is the actual network output vector, a function of the input data and network weights. This weight adjustment is repeated for many training samples and is stopped when the errors reach a sufficiently low level.

The majority of neural network applications are based on the backpropagation algorithm. The term backpropagation refers to the process by which derivatives of the network error, with respect to network weights and biases, are calculated, from the last layer of the network to the first. The Levenberg-Marquardt backpropagation scheme is one such technique used to optimize neural network weights, however any other applicable method may be used without departing from the scope of the invention.

When modelling a combustion propulsion engine, such as but not limited to a jet engine or rocket engine, it may be desirable to have both a visualization of the fluid dynamics of the system and a time sequence model of the fluid dynamics of the system. In some embodiments other parameters of interest may alternatively be modelled such as but not limited to the forces created within the system and the like.

A convolutional neural network (CNN, or ConvNet) is a class of deep neural networks, most commonly applied to analyzing visual imagery. Convolutional networks were inspired by biological processes in that the connectivity pattern between neurons resembles the organization of the animal visual cortex. Individual cortical neurons respond to stimuli only in a restricted region of the visual field known as the receptive field. The receptive fields of different neurons partially overlap such that they cover the entire visual field.

CNNs use relatively little pre-processing compared to other image classification algorithms. This means that the network learns the filters that in traditional algorithms were hand-engineered. This independence from prior knowledge and human effort in feature design is a major advantage. They have applications in image and video recognition, recommender systems, image classification, medical image analysis, and natural language processing. In accordance with an exemplary embodiment a CNN is applied as part of a modeling system for a combustion propulsion engine.

A recurrent neural network (RNN) is a class of artificial neural networks where connections between nodes form a directed graph along a temporal sequence. This allows it to exhibit temporal dynamic behavior. Unlike feedforward neural networks, RNNs can use their internal state (memory) to process sequences of inputs. This makes them applicable to tasks such as unsegmented, connected handwriting recognition or speech recognition as well as modelling of the dynamics of a combustion propulsion engine.

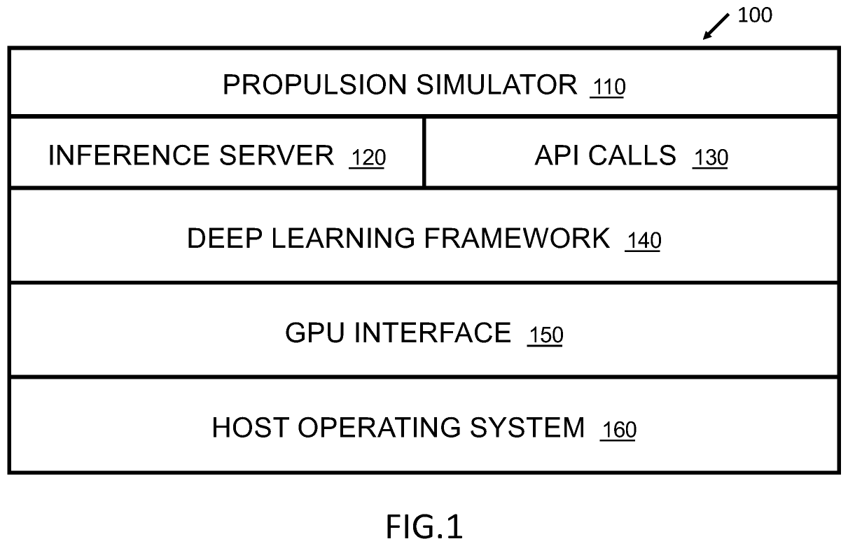

Referring now to FIG. 1, an exemplary stack diagram 100 for implementing, on a server, a neural network-based modeling of a combustion propulsion engine is depicted. Stack 100 includes a propulsion simulator 110 which utilizes information from an inference server 120 and API calls for bringing together program modules to implement propulsion simulator 110. A deep learning framework, such as but not limited to a CNN, an RNN, or a Feed-Forward Network, is put together as implementing a nonlinear mapping of at least a portion of the simulator model. A Graphics Processing Unit (GPU) Interface 150 is utilized to run computations for the neural network being implemented. GPU Interface 150 is controlled by the Host Operating System 160 which may be any standard or customized operating system.

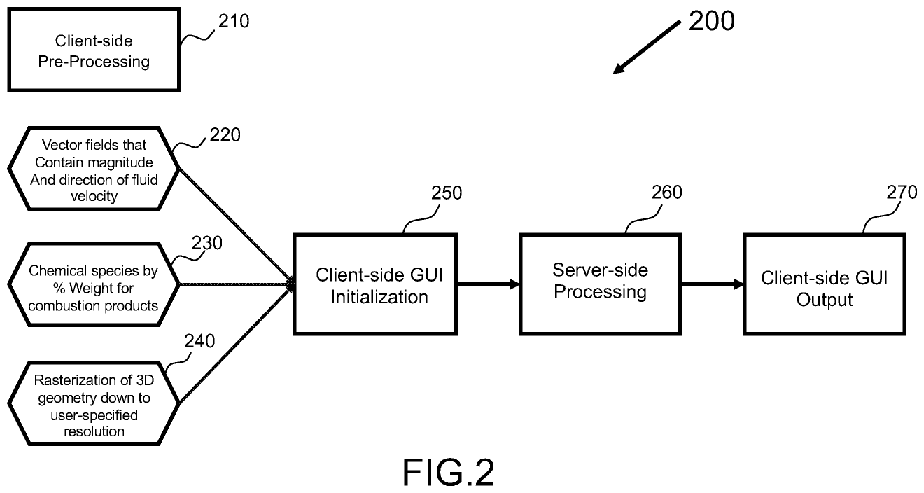

Referring now to FIG. 2, a flow diagram 200 depicts the information flow from input to output for the propulsion engine simulation. Flow 200 begins with Client-Side Pre-Processing 210 which may include any of a variety of preprocessing of data, such as but not limited to vector fields that contain magnitude and direction of fluid velocity 220, Chemical species by % Weight for combustion products 230, and Rasterization of 3D geometry down to user-specified resolution 240. Any preprocessed inputs may be supplied to the simulation system which may be helpful in both the training of the neural network and the performance of the neural network in providing high level simulation results. A Client-Side GUI Initialization 250 is available for a user to select the parameters and inputs for the simulation which is passed to Server-Side Processing 260 which hosts the software for one or more neural networks to carry out the primary part or parts of the simulation. In some exemplary embodiments, more than one neural network can be used each carrying out different portions of the simulation and linked from output of one network to inputs of another network. Also, any of a variety of neural network paradigms may be applied in any combination in order to most effectively provide high performance simulation results.

In accordance with an exemplary embodiment, the neural networks on the server are trained using data from either actual test data on similar combustion propulsion engines or may be trained on numerical simulation data. With respect to some embodiments, the neural networks may be trained on a combination of actual and simulation data. The high degree of nonlinearity and adaptivity of the neural network paradigms applied provide the ability to model the highly nonlinear fluid, structural, or combustion dynamics of a combustion propulsion engine. In accordance with exemplary embodiments, training may come from CFD results with coupling for turbulence or alternatively could come from a method whereby a three-dimensional (3D) point cloud of particles is tracked from the combustion chamber using radiographic methods. The training of the networks may be done using any of a variety of methods including, but not limited to Adam optimization and stochastic gradient descent methods.

In accordance with an exemplary embodiment, combustion chemistry may be modeled using a classic multilayer perceptron network, for example where inputs are, but are not limited to, chemical composition. And enthalpy and output is chemical composition. Fluid dynamics may be modeled using more complex network paradigms, for example recurrent networks with 3D Convolutional layers. Also, for the case of differing simulation resolutions, a Generative Adversarial Network (GAN) may be used.

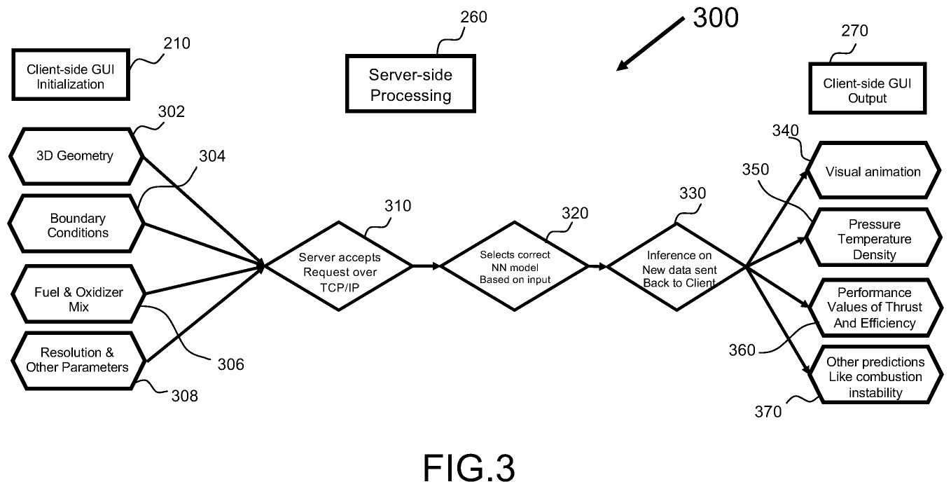

Referring now to FIG. 3, a more detailed view of the flow diagram of FIG. 2 is provided. In flow 300, preprocessing is provided in any of the same ways as discussed above with respect to FIG. 2 or may include providing 3D Geometry 302, Boundary Conditions 304, Fuel and Oxidizer mix ratios 306 or resolution and other parameters 308. Once the preprocessing has been completed, information is sent to the server, the server accepts a request over TCP/IP 310 and selects, based on the data received and based on the user inputs, the correct Neural Network model to use 320. The chosen model may be both the correct neural network paradigm as well as the correct trained network for the given portion of or volume of the combustion propulsion engine. Once the data has been run through the neural network models, Inference on the new data set is sent back to the client computer where postprocessing occurs based on commands received from the client computer GUI from the user. Post processing may include, but is not limited to Visual Animation 340; Pressure, Temperature, and Density 350; Performance Values of Thrust and Efficiency 360; or Other Predictions such as Combustion Instability 370. The inputs and outputs are not limited to those described but may be any of a variety of such inputs and outputs depending on design goals trying to be achieved.

In some instances, one or more components may be referred to herein as “configured to,” “configured by,” “configurable to,” “operable/operative to,” “adapted/adaptable,” “able to,” “conformable/conformed to,” etc. Those skilled in the art will recognize that such terms (e.g. “configured to”) generally encompass active-state components and/or inactive-state components and/or standby-state components, unless context requires otherwise.

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to claims containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that typically a disjunctive word and/or phrase presenting two or more alternative terms, whether in the description, claims, or drawings, should be understood to contemplate the possibilities of including one of the terms, either of the terms, or both terms unless context dictates otherwise. For example, the phrase “A or B” will be typically understood to include the possibilities of “A” or “B” or “A and B.”

With respect to the appended claims, those skilled in the art will appreciate that recited operations therein may generally be performed in any order. Also, although various operational flows are presented in a sequence(s), it should be understood that the various operations may be performed in other orders than those which are illustrated, or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

What is claimed is:

1. A combustion propulsion engine simulation system, comprising:
a first computer processor environment configured to preprocess data for providing to a simulation environment, the computer processor environment including a graphical user interface (GUI) for receiving input from a user;
a second computer processor environment running at least partially trained neural network software that has been trained to model the dynamics of at least a portion of a combustion propulsion engine when in use, the second computer processor environment receiving input information from the first computer processor environment; and
a third computer processor environment configured to receive data related to the output from the neural network of the second computer processor environment, the third computer processor environment providing post processing based on inputs received from a user through a GUI running on the third computer processor environment.

2. The combustion propulsion engine simulation system of claim 1, wherein the first and third computer processor environments are running on the same computer.

3. The combustion propulsion engine simulation system of claim 1, wherein the first, second, and third computer processor environments are running on the same computer.

4. The combustion propulsion engine simulation system of claim 1, wherein the second computer processor environment may run one or more of more than one configuration of neural network software.

5. The combustion propulsion engine simulation system of claim 1, wherein the neural network software comprises a multilayer perceptron network.

6. The combustion propulsion engine simulation system of claim 1, wherein the neural network software comprises a recurrent neural network.

7. The combustion propulsion engine simulation system of claim 1, wherein the neural network software comprises a convolutional neural network.

8. The combustion propulsion engine simulation system of claim 1, wherein neural network is trained based on simulation data from a computational fluid dynamic model.

9. The combustion propulsion engine simulation system of claim 1, wherein neural network is trained based on simulation data from experimental data.

10. The combustion propulsion engine simulation system of claim 1, wherein neural network is trained based on simulation data from experimental data, the experimental data at least partially derived from radiographic point cloud data.

11. The combustion propulsion engine simulation system of claim 1, wherein the preprocessing includes at least one of generating data relating to at least one of 3D geometry, boundary conditions, fuel and oxidizer mix, and simulation resolution.

12. The combustion propulsion engine simulation system of claim 1, wherein the post processing includes at least one of generating a visual animation, generating pressure, temperature, and density curves, generating performance values of thrust and efficiency; and predicting combustion stability.

13. A method of simulating dynamics of a combustion propulsion engine, comprising:
receiving input from a user through a graphical user interface (GUI) running on a first computer environment;
preprocessing data, by the first computer processor environment;
receiving input information, by a second computer processor environment, from the first computer processor environment;
running at least partially trained neural network software, by a second computer processor environment, that has been trained to model the dynamics of at least a portion of a combustion propulsion engine when in use;
receiving data, by a third computer processor environment, the data being related to the output from the neural network of the second computer processor environment,
providing post processing, by a third computer processor environment, the post processing based on inputs received from a user through a GUI running on the third computer processor environment.

14. The method of claim 13, wherein the first and third computer processor environments are running on the same computer.

15. The method of claim 13, wherein the first, second, and third computer processor environments are running on the same computer.

16. The method of claim 13, wherein the second computer processor environment may run one or more of more than one configuration of at least partially trained neural network software.

17. The method of claim 13, wherein the neural network software comprises at least one of a multilayer perceptron network, a recurrent neural network, and a convolutional neural network.

18. The method of claim 13, further comprising:
preprocessing data by at least one of generating data relating to at least one of 3D geometry, boundary conditions, fuel and oxidizer mix, and simulation resolution.

19. The method of claim 13, further comprising:
post, processing data from the neural network software by at least one of generating a visual animation, generating pressure, temperature, and density curves, generating performance values of thrust and efficiency; and predicting combustion stability.

20. The method of claim 13, further comprising:
adapting the weights of the neural network based on the output of the neural network during the simulation.

21. A system for simulating dynamics of a combustion propulsion engine, comprising:
a means for receiving input from a user through a graphical user interface (GUI) running on a first computer environment;
a means for preprocessing data, by the first computer processor environment;
a means for receiving input information, by a second computer processor environment, from the first computer processor environment;
a means for running at least partially trained neural network software, by a second computer processor environment, that has been trained to model the dynamics of at least a portion of a combustion propulsion engine when in use;
a means for receiving data, by a third computer processor environment, the data being related to the output from the neural network of the second computer processor environment,
a means for providing post processing, by a third computer processor environment, the post processing based on inputs received from a user through a GUI running on the third computer processor environment.
